(19) United States
(12) Patent Application Publication
(10) Pub. No.: US 2004/0007382 A1
(43) Pub. Date: Jan. 15, 2004

(54) Lithographic process using a chemical amplification resist and steps for limiting creep of the resist

(76) Inventor: Benedicte Mortini, Meylan (FR)

Correspondence Address: Andre M. Szuwalski, Jenkens & Gilchrist, P.C., Suite 3200, 1445 Ross Ave, Dallas, TX, 75201-2799, US

(21) Appl. No.: 10/459,118

(22) Filed: Jun. 10, 2003

(30) Foreign Application Priority Data
Jun. 18, 2002 (FR) 02 07516

(51) Int. Cl. H05K 1/00; G03F 7/20; G03F 7/30; G03F 7/38; G03F 7/40

(52) U.S. Cl. 174/253; 430/311; 430/328; 430/330; 430/394

(57) ABSTRACT

A lithographic process employing a resist for masking a substrate includes additional steps for limiting creep of the resist. The process is suitable for chemical amplification resists incorporating substrate protection agents sensitive to the same inactivation treatment as dissolution inhibitors of the resist. The additional steps are carried out after the development of the resist by dissolution. The steps include an additional step of sensitizing the residual resist on the substrate after the development, followed by a step of bringing the residual resist into contact with neutralization compounds.

### PRIORITY CLAIM

The present application claims foreign priority from French Application for Patent Serial No. 02 07516 filed Jun. 18, 2002, the disclosure of which is hereby incorporated by reference.

### BACKGROUND OF THE INVENTION

1. Technical Field of the Invention

The present invention relates to a lithographic process and, more particularly, to such a process suitable for a chemical amplification resist which is subject to creep.

2. Description of Related Art

A lithographic process allowing the creation of exposed areas and covered areas with a resist on the surface of a generally planar substrate is known. To do this, a radiation-sensitive resist is deposited on a surface of the substrate. The surface bearing the resist is then exposed to the sensitizing radiation through a mask which limits the exposure either to the areas intended to be uncovered or to the areas intended to remain covered with resist. The resist is then developed in a dissolution liquid in such a way that, for a positive resist, resist portions that have been presensitized are dissolved, while resist portions that have not been exposed to the sensitizing radiation are not dissolved. For a negative resist, only the sensitized resist portions remain on the substrate after development.

The sensitizing radiation may be of various types depending on the resist used. It is of the light type in the case of a photolithographic process requiring, for example, ultraviolet (UV) light or deep ultraviolet (deep UV) light. It may also consist of an electron bombardment of the resist. Depending on the case, the lithographic mask is designed to stop the light flux or the electron flux so as to define the areas of the resist that are exposed and not exposed to the sensitizing radiation.

After the resist has been developed, the surface of the substrate is subjected to a given treatment. The resist was chosen beforehand so as to protect the covered areas of the surface of the substrate from the effects of this treatment. To fabricate integrated electronic circuits, substrate treatments allowing the use of lithographic processes are, for example, treatments for implanting dopant species or plasma etching, called “dry etching”. During these implantation or etching treatments, the surface of the substrate is exposed to a flux of particles stopped by the resist in the covered areas of the surface of the substrate. The substrate treatment may also be a chemical etching treatment using a liquid solution incorporating suitable reactants, called “wet etching”. The resist must then be impermeable to the penetration of the solution.

The features of the lithographic mask are determined according to the profiles of the areas of the substrate surface in which the substrate treatment must take effect. In order for these areas to have, after the substrate treatment, profiles corresponding to the lithographic mask, it is necessary that no creep, no spreading and no deformation of the resist occur in the covered areas of the substrate between the development of the resist and the end of the substrate treatment.

The trend of electronic circuits towards greater levels of integration requires the resist to have a particularly high resistance to creep, spread and deformation in relation to the very small dimensions of the electronic components produced.

Moreover, in some electronic circuit fabrication technologies corresponding to particularly high levels of integration, because of diffraction effects, UV sensitizing light having a wavelength of less than or equal to 193 nanometers must be used in the lithographic process so as to reduce the minimum dimension of the areas created in the resist. This is in particular the case for sub-0.12 micron technologies capable of creating circuits having dimensions of less than 120 nanometers.

Standard resists having unsaturated chemical bonds therefore cannot be used, since their light absorption for wavelengths of less than or equal to 193 nanometers prevents the resist from being sensitized over its entire thickness.

Among resists compatible with UV sensitizing light having a wavelength of less than or equal to 193 nanometers, chemical amplification resists may be used. Such resists are essentially formed from polymer chains intrinsically soluble in a given development solution. They are initially rendered insoluble by dissolution inhibitors incorporated in the resist. These dissolution inhibitors may, in particular, be groups linked to the polymer chains.

These resists also include agents for generating compounds capable of inactivating the dissolution inhibitors. The generating agents produce compounds for inactivating the dissolution inhibitors when the resist is exposed to the sensitizing radiation. The dissolution inhibitors are then inactivated by the inactivation compounds after the resist has been suitably heated. The polymer chains then recover their solubility and the resist areas that were exposed to the sensitizing radiation may be dissolved. Such lithography resists are called chemical amplification resists when the same generating agent produces a compound which inactivates several or even a large number of dissolution inhibitors.

In chemical amplification resists, compounds for inactivating the dissolution inhibitors may unintentionally diffuse into or appear in the resist areas not exposed to the sensitizing radiation. However, the reduced amount of these compounds in the unexposed resist areas does not allow the unexposed resist to dissolve during development.

In some chemical amplification resists compatible with sensitizing light of a wavelength less than or equal to 193 nanometers, the substrate is protected from the effects of the treatment intended for the exposed areas by protective entities incorporated into the resist which are also sensitive to the inactivation compounds. These protective entities, or substrate protection agents, which may also be specific groups linked to the polymer chains of the resist, may in particular be sensitive to the treatment for inactivating the dissolution inhibitors.

The inactivation compounds unintentionally present in the unexposed resist areas impair a number of substrate protection agents during a subsequent heating of the resist that may occur, in particular, during the treatment intended for the exposed areas of the substrate. This therefore results in a particular mechanical destabilization of the resist, in the form of a resist creeping at the periphery of the covered areas.

It is known (for example, see U.S. Pat. No. 6,057,084) to bring a chemical amplification resist applied by photolithography on a substrate into contact with amine-type gaseous compounds after the resist has been developed. It is also known to combine this treatment by a gaseous compound with a photostabilization treatment of the resist, combining UV radiation and heating that are applied simultaneously. Such a post-lithographic treatment carried out on a resist based on polyhydroxystyrene (PHS)-type polymers makes it possible to limit a contraction of the resist portions remaining after development.

In a PHS resist, the hydroxystyrene units of the polymer give the resist its ability to protect the substrate from bombardment by particles used for etching or implantation of the substrate. These hydroxystyrene protective units are not impaired by the acid compounds for inactivating the dissolution inhibitors of the PHS resist, so that there is no creep of the resist caused by the hydroxystyrene units.

Moreover, the PHS resists are not compatible with UV light having a wavelength of less than or equal to 193 nanometers because of the presence of aromatic rings. They are sensitized with light having a wavelength of 248 nanometers, which does not allow the production of components having dimensions of less than 130 nanometers.

However, for a chemical amplification resist whose substrate protection agents are sensitive to the same inactivation treatment as the dissolution inhibitors, a single treatment by amine-type gaseous compounds carried out after the resist has been developed is insufficient to prevent the latter from creeping. This is because such a resist is particularly subject to creep because of the reactivity of the substrate protection agents to the inactivation compounds. Moreover, the UV radiation of the photostabilization treatment described above generates inactivation compounds which, because of the heating carried out simultaneously, inactivate both the substrate protection agents and the dissolution inhibitors of this resist. This therefore causes the resist to creep during the photostabilization treatment.

### SUMMARY OF THE INVENTION

There accordingly exists a need to limit the creep of a chemical amplification resist in those portions that are not exposed to the sensitizing radiation, thus allowing the production of components having dimensions of less than 130 nanometers.

The present invention relates to a lithographic process including:

a) depositing, on a surface of a substrate, a resist incorporating dissolution inhibitors and protection agents for protecting the substrate from the effects of a given treatment, the substrate protection agents being sensitive to a treatment for inactivating the dissolution inhibitors;

b) exposing the surface carrying the resist to a first sensitizing radiation through a mask defining masked areas and exposed areas of the resist, so as to generate a first type of compound in the exposed areas;

c) heating the resist so that the compounds of the first type inactivate at least some of the dissolution inhibitors in the exposed areas; and

d) developing the resist by means of a dissolution liquid so as to selectively dissolve the resist in the exposed areas.

According to the invention, the lithographic process may further comprise:

e) exposing at least part of the surface of the substrate to a second sensitizing radiation so as to generate compounds of the first type in at least some of said masked areas; and

f) neutralizing the compounds of the first type with compounds of a second type which are brought into contact with the residual resist.

In the process of the invention, compounds of the first type generated during heating, inactivate the dissolution inhibitors in said masked areas of the resist, and are then neutralized. The substrate protection agents are then preserved in said masked areas, thus reducing or eliminating any subsequent creep of the resist due to unintentionally inactivated substrate protection agents.

As a result, the resist areas created on the surface of the substrate during steps a) to d) do not undergo creep deformation up to the end of a substrate treatment carried out subsequently. This preservation of the shape of the resist areas makes it possible in particular, when light having a wavelength of less than or equal to 193 nanometers is used to sensitize the resist, to reduce the dimensions of these areas to below 130 nanometers. The dimensions of electronic components produced on the substrate on the base of these areas are then also less than 130 nanometers.

Another advantage of the process of the invention lies in the improved integrity of the resist during plasma etching or other substrate treatment, resulting from the preservation of the substrate protection agents.

According to the preferred method of implementing the process of the invention, the compounds of the second type, brought into contact with the residual resist during step f), are contained in a gas. To do this, compounds of the second type may, for example, be evaporated by bubbling a carrier gas through a liquid of said compounds of the second type, the carrier gas then being directed onto the surface of the substrate. Because the compounds of the second type are in gaseous form, they can diffuse into the resist so as to neutralize the compounds of the first type within it, without causing the resist of the masked areas to either swell or creep. In particular, the compounds of the second type may be brought into contact with said masked areas for a time of greater than 10 seconds, allowing most of the compounds of the first type present in said masked resist areas to be neutralized.

Optionally, in order to activate the diffusion of the compounds of the second type into the resist, the temperature of the residual resist may be increased during step f). This temperature must nevertheless remain below the maximum temperature reached by the resist during the heating of step c) so as not to impair the substrate protection agents in said masked resist areas.

Depending on the nature of the resist used, the first and/or the second sensitizing radiation may be light or electron irradiation, in the second case this being formed by an electron beam directed onto the resist. In particular, the first radiation and the second radiation may be of the same type, for example both being UV radiation, while having different radiation characteristics such as, especially, the radiation wavelength, the radiation energy density or the duration of exposure to this radiation.

Preferably, said masked resist areas receive, in step e) of the process of the invention, a radiation energy density at least equal to 5% of the radiation energy density received by said areas exposed in step b). This is because such a proportion allows a sufficient amount of compounds of the first type to be neutralized in said masked areas during step f) so as to prevent substantial creep of the resist in these areas.

The substrate treatment carried out after the lithographic process of the invention is, for example, a plasma etching treatment, a chemical etching treatment using a liquid solution, a doping implantation treatment, a surface treatment using a gas, and the like. The resist used in each case must protect the surface of the substrate in the covered areas from the effects of the treatment.

The invention also relates to a substrate treated by a lithographic process as described above. Such a substrate may include electronic components having at least one dimension less than 130 nanometers, measured parallel to the surface of the substrate.

Finally, the invention relates to an electrical device comprising a substrate thus treated. The electrical operation of such a device is improved and its cost reduced, these aspects being linked to the high level of integration of the electronic components contained in this device.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIG. 1 shows a polymer of a lithographic resist that can be employed in the process of the invention;

FIG. 2 is a block diagram of the steps of the process of the invention;

FIG. 3 shows a feature for testing the creep of a resist; and

FIG. 4 is a diagram showing creep characteristics of a resist corresponding to FIG. 1 and employed in the process of FIG. 2, for the test feature of FIG. 3.

### DETAILED DESCRIPTION OF THE DRAWINGS

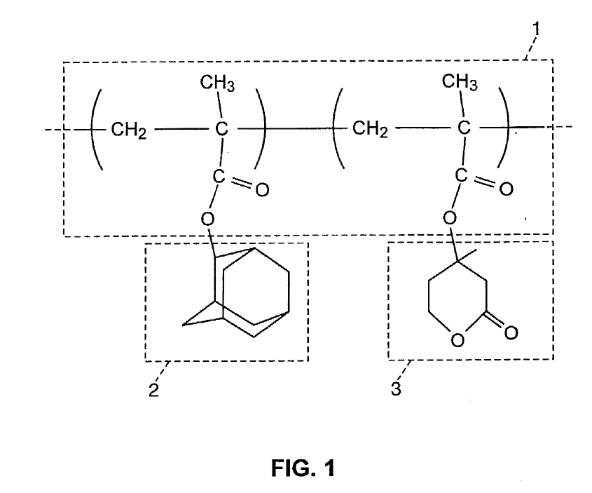

The invention applies, for example, to resists based on a modified methacrylate (MM) polymer that are compatible with sensitizing light having a wavelength of 193 nanometers. Such a polymer, shown in FIG. 1, comprises two types of groups 2 and 3 linked to a polymethacrylate chain 1 via the acid functional groups of this chain. The groups 2 make the polymer resistant to plasma etching. These are, for example, saturated rings of the 2-methyl-2-adamantanol type, which do not absorb at a wavelength of 193 nanometers. The groups 3 are, for example, of the mevalonic lactone cyclic ester (or “mevalonic lactone”) type and make the polymer resistant to being dissolved in a basic solution.

Furthermore, these MM resists also incorporate an acid precursor which produces an acid under the effect of UV radiation having a wavelength, for example, of 193 nanometers. The acid produced, corresponding to the previously introduced compounds of the first type, then break the bonds between the chain 1 and the groups 3 so that the polymer becomes soluble in a basic aqueous solution. It is necessary to heat the resist in order for this action by the acid to take place. The bonds between the chain 1 and the groups 2 are simultaneously broken due to the effect of the acid.

Thanks to their compatibility with short wavelength light radiation, the MM resists allow features having dimensions of less than 130 nanometers to be produced.

However, the MM resists as described above are particularly sensitive to creep after they have been developed. This is because the acid generated in the exposed areas for separating therein the dissolution inhibitor groups 3 from the chain 1 may diffuse into the unexposed areas, and,then separate the protective groups 2 in these unexposed areas from the chain 1. This release of the protective groups 2 induces mechanical destabilization of the residual resist after development, resulting in particularly pronounced creep, in particular during an etching or implantation treatment carried out on the surface of the substrate after the lithographic treatment.

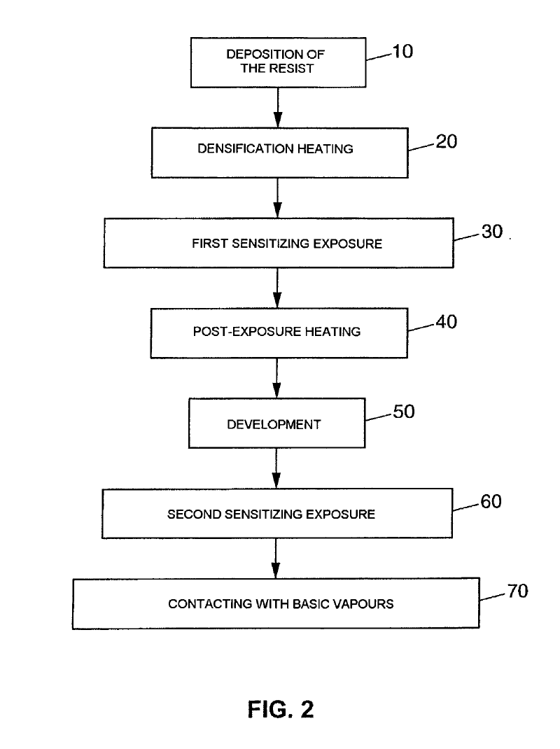

FIG. 2 lists the steps of a process according to the invention suitable for using an MM resist as described above.

In a first step (step 10), a liquefied MM resist is deposited and spread uniformly over the surface of a planar substrate using a known method such as, for example, spin coating. Optionally, the surface of the substrate has been treated beforehand with a compound such as hexamethyldisilazane (HMDS) so as to improve the adhesion of the resist to the substrate. Once the resist has been deposited, it is dried and subjected to stabilization heating (step 20, commonly referred to as a “soft bake”) for stabilizing it by densification and relaxation of the stresses present in the resist. The resist layer then has a thickness of about 300 nanometers. Characteristics of this stabilization heating are, for example, a resist temperature of 130° C. and a heating time of about one minute.

The substrate surface thus covered with resist is then exposed to UV sensitizing light having a wavelength of 193 nanometer (step 30). This first sensitizing exposure is carried out using a photolithography mask placed between the UV light source and the surface of the substrate, in a manner known per se, so as to define masked resist areas and exposed resist areas on the surface of the substrate. This first exposure is carried out so that the resist receives a light energy density of 17 millijoules per square centimeter of substrate surface, integrated over the entire duration of the exposure. The acid precursor generates the acid under the effect of the UV photons.

A heating step (step 40, commonly referred to as a “post-exposure bake”) is then carried out after the sensitizing exposure so that the acid produced inactivates the dissolution inhibitors in the exposed resist portions. This inactivation takes place, for an MM resist corresponding to FIG. 1, by the chemical bond between said dissolution inhibitors 3 and the polymethacrylate chain 1 being broken by the effect of the acid produced. The temperature of the resist during this heating, for example for one minute, is about 130° C.

The resist is then developed (step 50) in a basic aqueous solution, using a method known to those skilled in the art. The exposed resist portions are dissolved and the areas of the substrate surface carrying these exposed resist portions are bared.

The substrate surface then carries only the resist portions masked during the exposure 30. It is exposed to a second sensitizing radiation (step 60) without a photolithography mask. This second exposure again uses UV light having a wavelength of 193 nanometers, but with an energy density of 3.6 millijoules per square centimeter of exposed surface, integrated over the entire duration of this second exposure. Acid is consequently generated in the residual resist portions present on the surface of the substrate, but with an acid concentration of less than that generated during the first sensitizing exposure 30.

The substrate surface with the residual resist is then brought into contact with vapors of a basic compound, corresponding to the previously introduced compound of the second type, in a specially adapted sealed chamber (step 70). To do this, a carrier gas such as nitrogen is bubbled through a container in which the basic compound in liquid form is contained, so that some of the basic compound is evaporated and carried off by the carrier gas. The gas thus obtained is sent onto the substrate surface in the form of a gas curtain beneath which the surface of the substrate is made to run. The basic compound then penetrates, by diffusion, into the residual resist portions and neutralizes the acid generated therein during the second sensitizing exposure 60, according to an acid/base neutralization reaction.

After step 70, the residual resist areas no longer contain acid, and the amount of residual acid generators in these areas is reduced. The substrate protection groups 2 and dissolution inhibitors 3 consequently cannot be subsequently separated from the chain 1, thereby preventing any creep of the resist caused by the protective groups .2, even when the temperature of the resist is raised.

The basic compound used to neutralize the acid for inactivating the inhibiting groups may be of a different type, especially ammonia, an amine, compounds of the silazane or silazane-derivative type, such as for example hexamethyldisilazane (HMDS) of semi-developed formula (CH₃)₃Si—NH—Si—(CH₃)₃, compounds of the pyrrolidone or pyrrolidone-derivative type such as, for example, N-methylpyrrolidone, or else a mixture comprising some of these compounds.

When implementing the process reported here, hexamethyldisilazane (HMDS) vapors were produced by bubbling nitrogen at atmospheric pressure, at a rate of 3 liters per minute, through an HMDS container maintained at a temperature of about 90° C.

The temperature of the residual resist may be intentionally increased when contacting the resist with the HMDS vapors so as to activate the diffusion of these vapors into the resist. The acid generated in the residual resist is then more completely neutralized. However, the temperature of the residual resist during the second sensitizing exposure 60 and the temperature of the resist while it is being contacted with the HMDS vapors during step 70 must necessarily remain below the temperature of the resist during the heating of step 40. This is because if such a temperature is again reached, groups 2 and 3 are released in the residual portions of the resist, causing the latter to be destabilized and to creep.

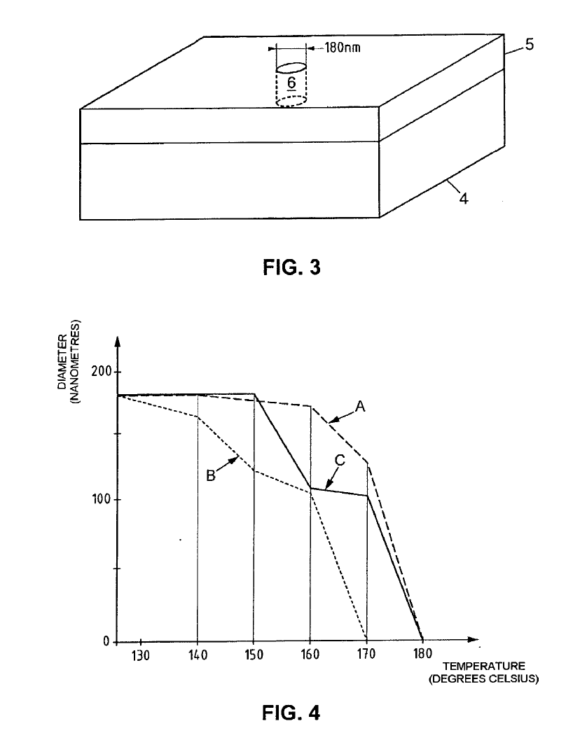

FIG. 3 shows a resist feature used to demonstrate the effectiveness of the process described above for protecting the resist from creeping after this process has been carried out. An MM-type resist was deposited in the manner described above on a planar substrate 4 in the form of a layer 5 having a uniform thickness of about 300 nanometers. A mask was used during the first sensitizing exposure 30 blocking off all of the resist apart from a disc 180 nanometers in diameter (see FIG. 3). After the development step 50, the resist layer therefore had a single circular hole 6 corresponding to the feature of the mask. Such a feature corresponds, for example, to the production of contact holes in an insulating material in order to produce vias between superimposed metallization levels.

Steps 60 and 70 are carried out in the manner described above.

The resist with the hole 6 is then subjected to a creep test, consisting in progressively heating the resist and in plotting, on the diagram in FIG. 4, the change in the diameter of the circular hole 6 as a function of temperature. This diameter decreases when the temperature becomes high enough to cause the resist to creep. Curve C (FIG. 4) corresponds to the creep test carried out after the process of the invention, that is to say after the second sensitizing exposure (step 60) and after the step of contacting with basic vapors (step 70). This curve shows that the creep onset temperature of the resist used according to the process of the invention is 150° C., corresponding to the temperature at which the diameter of the hole 6 starts to decrease.

For comparison, curves A and B correspond to resist creep tests identical to the previous one, carried out on an identical MM resist, but at different moments during the lithography process. Curve A corresponds to a creep test carried out after the resist has been developed (step 50), before the second sensitizing exposure (step 60), and curve B corresponds to a creep test carried out after the second sensitizing step (step 60), before the contacting with the basic vapors (70). The initial feature in the resist in the form of a circular hole is identical to that used for curve C.

The creep onset temperature read off curve A is 160° C. It corresponds to a resist that has never been sensitized by UV light, and therefore contains no acid compounds. The groups 2 and 3 therefore remain linked to the polymer chain 1, preserving the mechanical stability of the resist.

The creep onset temperature read off curve B is less than 130° C. It corresponds to a resist in which, after development, a certain amount of acid compounds have been generated. Creep is initiated therein when the temperature comes close to 130° C., that is to say for a value approximately equal to the temperature of the heating of step 40. This is then sufficient for the acid compounds to release the groups 2 responsible for the creep.

Consequently, curve C shows that step 70 of neutralizing the acid compounds generated by basic compounds allows the resist to recover at least some of its resistance to creep caused by overheating. It also prevents premature creep of the resist caused by acid compounds that have unintentionally diffused into the masked resist portions during the first sensitizing exposure.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A lithographic process comprising:
a) depositing, on a surface of a substrate, a resist incorporating dissolution inhibitors and protection agents for protecting the substrate from the effects of a given treatment, the substrate protection agents being sensitive to a treatment for inactivating the dissolution inhibitors;
b) exposing the surface carrying the resist to a first sensitizing radiation through a mask defining masked areas and exposed areas of the resist, so as to generate a first type of compounds in the exposed areas;
c) heating the resist so that the compounds of the first type inactivate at least some of the dissolution inhibitors in the exposed areas;
d) developing the resist by means of a dissolution liquid so as to selectively dissolve the resist in the exposed areas;
e) exposing at least part of the surface of the substrate to a second sensitizing radiation so as to generate compounds of the first type in at least some of said masked areas; and
f) neutralizing the compounds of the first type with compounds of a second type which are brought into contact with the residual resist.

2. The process according to claim 1, wherein the compounds of the second type are contained in a gas.

3. The process according to claim 1, wherein the compounds of the first and second types are acid and basic compounds, respectively.

4. The process according to claim 3, wherein the compounds of the second type are ammonia, an amine, compounds of the silazane or silazane-derivative type, compounds of the pyrrolidone or pyrrolidone-derivative type, or a mixture comprising some of the above compounds.

5. The process according to claim 1, wherein the compounds of the first type inactivate the dissolution inhibitors by breaking a chemical bond between said dissolution inhibitors and a polymer of the resist.

6. The process according to claim 1, which furthermore includes, between a) and b), a heating step to stabilize the resist.

7. The process according to claim 1, wherein the first and/or the second sensitizing radiation is light radiation.

8. The process according to claim 7, wherein the first sensitizing radiation used in b) to generate compounds of the first type in said exposed areas is light radiation having a wavelength of less than or equal to 193 nanometers.

9. The process according to claim 7, wherein the second sensitizing radiation used in e) to generate compounds of the first type in said masked areas is light radiation having a wavelength of less than or equal to 193 nanometers.

10. The process according to claim 1, wherein the resist areas created during a) to d) have at least one dimension of less than 130 nanometers measured parallel to the surface of the substrate.

11. The process according to claim 1, wherein said masked areas receive, in e), a radiation energy density at least equal to 5% of the radiation energy density received by said areas exposed in b).

12. The process according to claim 1, wherein, in f), the compounds of the second type are brought into contact with said masked areas for a time of greater than 10 seconds.

13. The process according to claim 1, wherein, in f), the residual resist is raised to a temperature below the maximum temperature reached by the resist during the heating of c).

14. A substrate created by the lithographic process of claim 1.

15. The substrate according to claim 14, comprising electronic components having at least one dimension of less than 130 nanometers, measured parallel to the surface of the substrate.

16. An electrical device including a substrate created by the process of claim 1.

17. The device according to claim 16, comprising electronic features having at least one dimension of less than 130 nanometers, measured parallel to the surface of the substrate.

18. A semiconductor fabrication process wherein unexposed areas of a resist exist on a substrate surface, the process comprising:
exposing the substrate to radiation without use of a lithographic mask to release an acid from the unexposed areas of resist; and
exposing the substrate to a basic compound to neutralize the released acid in the unexposed areas and inhibit creep of the unexposed areas of resist during subsequent processing.

19. The method of claim 18 wherein the resist is a modified methacrylate polymer-based resist.

20. The method of claim 18 wherein the resist is a polymer chain to which is linked a substrate protection group and a dissolution inhibitor group.

21. The method of claim 20 wherein creep prevention accrues because the acid, once neutralized, is no longer available in the unexposed areas of resist to break the substrate protection group from the polymer chain during subsequent processing.

22. The method of claim 18 wherein the basic compound is gaseous.

23. The method of claim 22 wherein the gaseous basic compound penetrates, by diffusion, into the unexposed areas of resist to neutralize the released acid.

24. The method of claim 18 wherein the resist is a chemical amplification resist incorporating a substrate protection agent which is sensitive to a same inactivation treatment as a dissolution inhibitor present within the resist.

25. A method for semiconductor fabrication, comprising:
using lithographic processing techniques to define an unexposed area of resist on a substrate which defines a feature having a width dimension of less than or equal to 180 nanometers; and
processing the unexposed area of resist to inhibit creep of the resist beyond the 180 nanometer width during subsequent processing of the substrate.

26. The method of claim 25 wherein the processing inhibits creep of the resist with respect to subsequent processing of the substrate which occurs at temperatures less than about 150 degrees Celsius.

27. The method of claim 25 wherein the processing includes:
exposing the substrate to radiation without use of a lithographic mask to release an acid from the unexposed areas of resist; and
exposing the substrate to a basic compound to neutralize the released acid in the unexposed areas.

28. The method of claim 27 wherein the basic compound is gaseous.

29. The method of claim 28 wherein the gaseous basic compound penetrates, by diffusion, into the unexposed areas of resist to neutralize the released acid.

30. The method of claim 25 wherein the resist is a modified methacrylate polymer-based resist.

31. The method of claim 25 wherein the resist is a polymer chain to which is linked a substrate protection group and a dissolution inhibitor group.

32. The method of claim 31 wherein processing inhibits creep because the acid, once neutralized, is no longer available in the unexposed areas of resist to break the substrate protection group from the polymer chain during subsequent processing.

33. The method of claim 25 wherein the resist is a chemical amplification resist incorporating a substrate protection agent which is sensitive to a same inactivation treatment as a dissolution inhibitor present within the resist.
